(19) United States
(12) Patent Application Publication
(10) Pub. No.: US 2025/0105798 A1
(43) Pub. Date: Mar. 27, 2025

(54) CLAMPING CIRCUIT AND AMPLIFIER

(71) Applicant: Murata Manufacturing Co., Ltd., Kyoto (JP)

(72) Inventors: Satoshi GOTO, Kyoto (JP); Masao KONDO, Kyoto (JP); Kenji SASAKI, Kyoto (JP); Shinnosuke TAKAHASHI, Kyoto (JP)

(21) Appl. No.: 18/975,469

(22) Filed: Dec. 10, 2024

Related U.S. Application Data
(63) Continuation of application No. PCT/JP2023/020085, filed on May 30, 2023.

(30) Foreign Application Priority Data
Jul. 11, 2022 (JP) 2022-111158

(51) Int. Cl. H03F 1/52; H03F 3/24

(52) U.S. Cl. CPC H03F 1/52; H03F 3/245; H03F 2200/426; H03F 2200/451

(57) ABSTRACT

A clamping circuit is connected between a ground potential and a node through which a radio frequency signal passes. The clamping circuit includes multiple clamping elements that are cascaded. Each of the multiple clamping elements becomes conductive when a voltage greater than or equal to a forward voltage is applied thereto. At least one of the multiple clamping elements is implemented by a resistor-connected transistor that includes a bipolar transistor and a base-collector resistance element connected between the base and the collector of the bipolar transistor.

### CROSS REFERENCE TO RELATED APPLICATION

This is a continuation of International Application No. PCT/JP2023/020085 filed on May 30, 2023 which claims priority from Japanese Patent Application No. 2022-111158 filed on Jul. 11, 2022. The contents of these applications are incorporated herein by reference in their entireties.

### BACKGROUND ART

### Technical Field

The present disclosure relates to a clamping circuit and an amplifier.

A radio frequency power amplifier is one of major components of a mobile terminal. Radio communication standards, such as carrier aggregation (CA), that use many frequency bands have been put into practical use to increase the wireless transmission capacity of mobile terminals. As the number of used frequency bands increases, the circuit configuration of the RF front end becomes more complex. Also, to make the sub-6 GHz frequency band of the fifth generation mobile communication system (5G) usable, the circuit configuration of the RF front end becomes even more complex.

When the circuit configuration of the RF front end becomes complex, the loss caused by, for example, filters and switches inserted in a transmission line extending from a radio frequency power amplifier to an antenna increases. As a result, the radio frequency power amplifier needs to be high-powered in addition to supporting multiple frequency bands.

The output current and output voltage of the radio frequency power amplifier vary greatly according to changes in the load impedance. The radio frequency power amplifier needs to be high-powered and needs to be improved in terms of voltage withstand characteristics associated with changes in the load impedance. An excessive increase in the output voltage is suppressed by inserting a clamping circuit between the output terminal (the collector of a bipolar transistor) of a power stage transistor of the radio frequency power amplifier and the ground. This suppresses the breakdown of the transistor.

Also, in a semiconductor device including both a high-voltage circuit and a low-voltage circuit, a clamping circuit is used to prevent a high voltage from being applied to the low-voltage circuit (for example, Patent Document 1). The clamping circuit includes multiple diodes that are cascaded in the forward direction. For example, diode-connected bipolar transistors are used as the diodes.
Patent Document 1: Japanese Unexamined Patent Application Publication No. 2009-164415

### BRIEF SUMMARY

When a predetermined clamp voltage is applied to the clamping circuit, the clamping circuit becomes conductive. When a voltage greater than or equal to the clamp voltage is applied to the ends of the clamping circuit, the voltage rise is limited, and the generation of an excessive voltage is reduced. The clamp voltage is equal to a value obtained by multiplying the forward voltage of each of the diodes constituting the clamping circuit by the number of stages of the diodes. Therefore, the clamp voltage corresponds to an integer multiple of the forward voltage of each of the multiple diodes.

As the RF front end becomes more and more complex, the required output of the radio frequency power amplifier also increases. The clamping circuit needs to satisfy the required output of a radio frequency power amplifier circuit and to also limit the output power so as not to exceed the breakdown limit. As the required output for radio frequency power amplification increases, the required output approaches the breakdown limit of the transistor. Therefore, it becomes suitable to finely adjust the degree of output power limitation (which may also be referred to as power clipping) for the radio frequency power amplifier circuit. With the related-art clamping circuit that can adjust the clamp voltage of the output node of the radio frequency power amplifier only to an integer multiple of the forward voltage of each of multiple diodes, it is difficult to finely adjust the degree of output power limitation such that the required output near the breakdown limit is met but the breakdown limit is not exceeded.

The output power can also be limited by connecting a clamping circuit to the input side of the radio frequency power amplifier and thereby limiting the input power. Even when the related-art clamping circuit is used on the input side, because the related-art clamping circuit can adjust the clamp voltage only to an integer multiple of the forward voltage of each of multiple diodes, it is difficult to finely adjust the degree of input power limitation such that the required output near the breakdown limit is met and the breakdown limit is not exceeded.

The present disclosure provides a clamping circuit that can finely adjust the degree of power limitation.

An aspect of the present disclosure provides a clamping circuit connected between a ground potential and a node through which a radio frequency signal passes. The clamping circuit includes multiple clamping elements that are cascaded. Each of the multiple clamping elements becomes conductive when a voltage greater than or equal to a forward voltage is applied thereto. At least one of the multiple clamping elements is implemented by a resistor-connected transistor that includes a bipolar transistor and a base-collector resistance element connected between the base and the collector of the bipolar transistor.

Another aspect of the present disclosure provides an amplifier including a radio frequency power amplifier circuit that amplifies a radio frequency signal input from an input node and outputs the amplified radio frequency signal from an output node and the clamping circuit that is connected between one of the input node and the output node of the radio frequency power amplifier circuit and a ground potential.

When a predetermined voltage is applied between the collector and the emitter of a resistor-connected transistor, the resistor-connected transistor becomes conductive. When the resistance value of a base-emitter resistance element of the resistor-connected transistor changes, the current and voltage characteristics of a clamping circuit change. Therefore, the degree of power limitation applied when the clamping circuit becomes conductive can be finely adjusted by adjusting the resistance value of the base-emitter resistance element.

### BRIEF DESCRIPTION OF THE DRAWINGS

FIG. 1A is an equivalent circuit diagram of an amplifier including a clamping circuit according to a first embodiment, and FIG. 1B is an equivalent circuit diagram of an amplifier including a clamping circuit according to a comparative example.

FIG. 2A is a graph schematically showing the relationship between an output voltage Vout and a clamp current Id of each of the clamping circuits according to the first embodiment (FIG. 1A) and the comparative example (FIG. 1B), and FIG. 2B is a graph schematically showing the relationship between output power Pout and gain of each of the amplifiers according to the first embodiment (FIG. 1A) and the comparative example (FIG. 1B).

FIG. 3A is an equivalent circuit diagram of a clamping circuit and an amplifier according to a second embodiment, FIG. 3B is an equivalent circuit diagram of a clamping circuit and an amplifier according to a comparative example, and FIG. 3C is an equivalent circuit diagram of an amplifier according to another comparative example.

FIG. 4A is a cross-sectional view of a portion in which diodes included in the clamping circuit of the second embodiment (FIG. 3A) are located, and FIGS. 4B and 4C are cross-sectional views of portions in which a resistor-connected transistor is located.

FIG. 5A is a diagram illustrating a positional relationship in plan view among components of the clamping circuit according to the second embodiment, and FIG. 5B is a diagram illustrating a positional relationship in plan view among components of the clamping circuit according to the comparative example (FIG. 3B).

FIG. 6A is an equivalent circuit diagram of a circuit used for simulations, and FIG. 6B is a graph showing a simulation result of the relationship between output power Pout and gain of each of the amplifiers according to the second embodiment (FIG. 3A) and the comparative examples (FIGS. 3B and 3C).

FIG. 7 is an equivalent circuit diagram of a clamping circuit and an amplifier according to a third embodiment.

FIG. 8 is a diagram illustrating the arrangement in plan view of a resistor-connected transistor and multiple diodes constituting the clamping circuit according to the third embodiment.

FIG. 9 is a graph showing a simulation result of the relationship between output power Pout and gain of each of the amplifiers according to the third embodiment (FIG. 7) and the comparative examples (FIGS. 3B and 3C).

FIG. 10 is an equivalent circuit diagram of a clamping circuit and an amplifier according to a fourth embodiment.

FIG. 11 is an equivalent circuit diagram of a clamping circuit and an amplifier according to a variation of the fourth embodiment.

FIG. 12 is an equivalent circuit diagram of a clamping circuit and an amplifier according to a fifth embodiment.

FIG. 13 is a graph showing a simulation result of the relationship between output power Pout and gain of each of the amplifiers according to the fifth embodiment (FIG. 12) and the comparative examples (FIGS. 3B and 3C).

FIG. 14 is an equivalent circuit diagram of a clamping circuit and an amplifier according to a variation of the fifth embodiment.

FIG. 15 is a graph showing a simulation result of the relationship between output power Pout and gain of each of the amplifiers according to the variation of the fifth embodiment (FIG. 14) and the comparative examples (FIGS. 3B and 3C).

FIG. 16A is an equivalent circuit diagram of a clamping circuit and an amplifier according to a sixth embodiment, and FIG. 16B is an equivalent circuit diagram of a clamping circuit and an amplifier according to a comparative example.

FIG. 17A is a graph showing simulation results of the relationship between input power Pin and gain, and FIG. 17B is a graph showing simulation results of the relationship between output power Pout and gain.

FIG. 18A is an equivalent circuit diagram of an amplifier according to a seventh embodiment, and FIG. 18B and FIG. 18C are equivalent circuit diagrams of amplifiers according to variations of the seventh embodiment.

FIG. 19 is an equivalent circuit diagram of an amplifier according to another variation of the seventh embodiment.

FIG. 20A, FIG. 20B, and FIG. 20C are equivalent circuit diagrams of amplifiers according to still other variations of the seventh embodiment.

FIG. 21A, FIG. 21B, and FIG. 21C are equivalent circuit diagrams of amplifiers according to still other variations of the seventh embodiment.

FIG. 22 is an equivalent circuit diagram of an amplifier according to an eighth embodiment.

FIG. 23 is an equivalent circuit diagram of an amplifier according to a variation of the eighth embodiment.

FIG. 24 is an equivalent circuit diagram of an amplifier according to another variation of the eighth embodiment.

FIG. 25 is an equivalent circuit diagram of an amplifier according to a ninth embodiment.

FIG. 26 is an equivalent circuit diagram of an amplifier according to a variation of the ninth embodiment.

FIG. 27 is an equivalent circuit diagram of an amplifier according to another variation of the ninth embodiment.

FIG. 28 is an equivalent circuit diagram of an amplifier according to a tenth embodiment.

### DESCRIPTION OF EMBODIMENTS

### First Embodiment

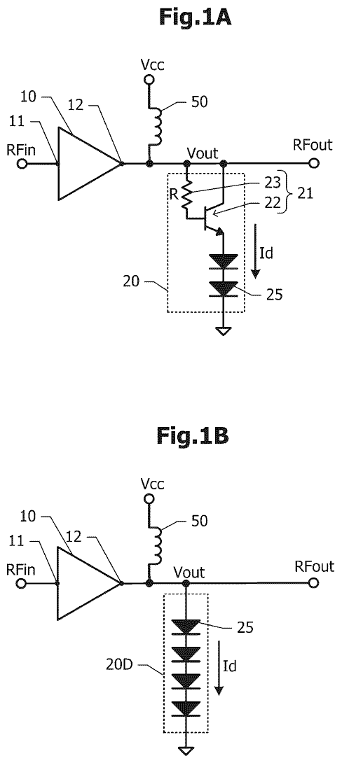

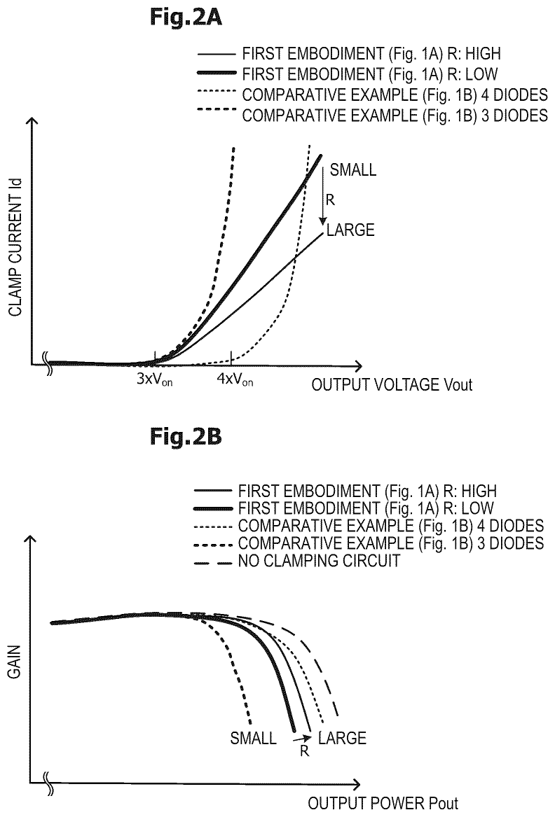

A clamping circuit and an amplifier according to a first embodiment are described below with reference to FIG. 1A through FIG. 2B.

FIG. 1A is an equivalent circuit diagram of an amplifier including a clamping circuit according to the first embodiment. A radio frequency signal RFin is input to an input node 11 of a radio frequency power amplifier circuit 10 (hereafter simply referred to as an “amplifier circuit”), and the amplified radio frequency signal is output from an output node 12. The amplifier circuit 10 includes, for example, multiple heterojunction bipolar transistors (HBTs) that are connected parallel to each other. A power supply voltage Vcc is applied via a choke coil 50 to the output node 12, that is, the collectors of the multiple HBTs.

A clamping circuit 20 is connected between the output node 12 and a reference potential (hereafter referred to as a ground potential). That is, the clamping circuit 20 is connected between the ground potential and a node through which a radio frequency signal passes. The clamping circuit 20 includes multiple, for example, three, clamping elements that are cascaded (connected in series). One of the multiple clamping elements is a resistor-connected transistor 21, and the other two of the multiple clamping elements are diodes 25. The diodes 25 may be implemented by, for example, general p-n junction diodes. The clamping circuit 20 becomes conductive when the peak value of a radio frequency voltage generated between the output node 12 and the ground potential exceeds a predetermined voltage value and thereby limits the peak value of the radio frequency voltage between the output node 12 and the ground potential.

When the clamping circuit 20 becomes conductive, a part of the radio frequency signal output from the output node 12 flows through the clamping circuit 20, and the remaining radio frequency signal RFout is supplied to a subsequent circuit, such as a load.

The resistor-connected transistor 21 includes a bipolar transistor 22 (hereafter referred to as a “transistor 22”) and a base-collector resistance element 23 connected between the base and the collector of the transistor 22. The collector of the transistor 22 is connected to the output node 12. The multiple cascaded diodes 25 are connected between the emitter of the transistor 22 and the ground potential. Each of the multiple diodes 25 is connected in the forward direction from the output node 12 toward the ground potential.

When a voltage greater than or equal to the forward voltage is applied to each diode 25, a forward current flows through the diode 25. The forward voltage of the diode 25 is represented by Von. The electric current (hereafter referred to as a clamp current) flowing through the clamping circuit 20 is represented by Id, the resistance value of the base-collector resistance element 23 is represented by R, and the current amplification factor of the transistor 22 is represented by B. The base-emitter voltage of the transistor 22 is represented by Vbe.

When a voltage greater than the base-emitter voltage Vbe is applied to the resistor-connected transistor 21, the transistor 22 becomes conductive. The voltage drop caused by the base-collector resistance element 23 on this occasion is represented by R×Id/(1+β). A collector-emitter voltage Vce of the transistor 22 is represented by R×Id/(1+β)+Vbe.

When the same layers as the emitter layer and the base layer of the transistor 22 are used, respectively, as the cathode layer and the anode layer of the diodes 25, the base-emitter voltage Vbe of the transistor 22 becomes equal to the forward voltage Von of the diodes 25. In this case, when a voltage greater than or equal to the forward voltage Von is applied to each of the resistor-connected transistor 21 and the diodes 25, the clamping circuit 20 becomes conductive.

When the clamp current Id flows through the clamping circuit 20, the voltage at the ends of the resistor-connected transistor 21 becomes higher than the forward voltage Von of each of the diodes 25 by R×Id/(1+B). That is, the resistor-connected transistor 21 is equivalent to a circuit in which a resistor with a resistance value R/(1+β) is connected in series with the diodes 25.

Next, with reference to FIG. 1B, FIG. 2A, and FIG. 2B, the clamping characteristics of clamping circuits according to the first embodiment and a comparative example are described.

FIG. 1B is an equivalent circuit diagram of an amplifier including a clamping circuit 20D according to a comparative example. The clamping circuit 20D of the comparative example is constituted by series-connected four diodes 25 and does not include the resistor-connected transistor 21 (FIG. 1A).

FIG. 2A is a graph schematically showing the relationship between an output voltage Vout (the voltage of the output node 12) and the clamp current Id of each of the clamping circuits according to the first embodiment (FIG. 1A) and the comparative example (FIG. 1B). In the graph, the horizontal axis indicates the output voltage Vout, and the vertical axis indicates the clamp current Id. Here, each of the output voltage Vout and the clamp current Id indicates an instantaneous value of the radio frequency signal.

In the graph, each of a thin solid line and a thick solid line represents the clamp current Id of the clamping circuit 20 according to the first embodiment (FIG. 1A). As the resistance value R of the base-collector resistance element 23 increases, the clamp current Id changes from the characteristics indicated by the thick solid line toward the characteristics indicated by the thin solid line. A thin dotted line represents the clamp current Id of the clamping circuit 20D according to the comparative example (FIG. 1B), and a thick dotted line represents the clamp current Id of the clamping circuit 20D according to the comparative example (FIG. 1B) in which the number of diodes 25 is changed from four to three.

In the comparative example (FIG. 1B), the clamp current Id starts to flow when the output voltage Vout reaches 4×Von. When the number of diodes 25 is changed to three, the clamp current Id starts to flow when the output voltage Vout reaches 3×Von. The clamp current Id sharply rises as the output voltage Vout increases.

In the first embodiment (FIG. 1), the clamp current Id starts to flow when the output voltage Vout reaches 3×Von. Because the clamping circuit 20 according to the first embodiment is equivalent to a circuit in which a resistor with a resistance value R/(1+β) is connected in series with a multistage circuit constituted only by diodes, the rate of the increase in the clamp current Id associated with the increase in the output voltage Vout is more gradual compared with the comparative example. Also, as the resistance value R of the base-collector resistance element 23 increases, the inclination of the graph becomes more gradual.

FIG. 2B is a graph schematically showing the relationship between output power Pout and gain of each of the amplifiers according to the first embodiment (FIG. 1A) and the comparative example (FIG. 1B). In the graph, the horizontal axis represents the output power Pout, and the vertical axis represents the gain. Here, the output power Pout indicates the average power of the radio frequency signal.

Each of a thin solid line and a thick solid line in the graph indicates the gain of the amplifier according to the first embodiment (FIG. 1A). As the resistance value R of the base-collector resistance element 23 increases, the gain changes from the characteristics indicated by the thick solid line toward the characteristics indicated by the thin solid line. A thin dotted line indicates the gain of the amplifier according to the comparative example (FIG. 1B), and a thick dotted line indicates the gain of the amplifier observed when the number of diodes 25 of the clamping circuit 20D according to the comparative example (FIG. 1B) is changed from four to three. A long dashed line indicates the gain of an amplifier to which no clamping circuit is connected.

Compared to a case in which no clamping circuit is connected, the output power Pout is limited when the clamping circuit 20 or 20D is connected. In the comparative example (FIG. 1B), when the number of diodes 25 of the clamping circuit 20D is changed from four to three, the output power limitation amount (clipping amount) increases. The limitation amount of the output power Pout achieved by the amplifier according to the first embodiment (FIG. 1A) is greater than the limitation amount achieved by the clamping circuit 20D of the comparative example (FIG. 1B) including four diodes 25 and is less than the limitation amount achieved by the clamping circuit 20D including three diodes 25.

Next, advantageous effects of the first embodiment are described.

With the clamping circuit 20D of the comparative example (FIG. 1B) in which only diodes 25 are cascaded, the output voltage Vout at which the clamping circuit 20D starts to conduct electricity is limited to integer multiples of the forward voltage Von of each diode 25, and the rise of the clamp current Id becomes steep. Therefore, as shown in FIG. 2B, it is not possible to finely adjust the limitation amount of the output power Pout. For example, in the graph of FIG. 2B, it is not possible to achieve characteristics between the gain-output voltage characteristics of the comparative example including three diodes 25 and the gain-output voltage characteristics of the comparative example including four diodes 25.

For example, when the output power Pout, which is output when the clamping circuit 20D (FIG. 1B) of the comparative example has the four-stage configuration, exceeds the breakdown limit, the clamping circuit 20D needs to be changed to the three-stage configuration to prevent breakdown. When the clamping circuit 20D is changed to the three-stage configuration, the output power Pout is greatly limited as shown in FIG. 2B, and the required output may be unmet.

In contrast, in the first embodiment, as shown in FIG. 2B, characteristics intermediate between the gain-output voltage characteristics of the clamping circuit 20D of the comparative example with the three-stage configuration and the gain-output voltage characteristics of the clamping circuit 20D of the comparative example with the four-stage configuration can be achieved by including the resistor-connected transistor 21 in the clamping circuit 20. The output power limitation amount can be finely adjusted by adjusting the resistance value R of the base-collector resistance element 23 (FIG. 1A) such that the required output can be met but the output power Pout does not exceed the breakdown limit.

Furthermore, as shown in FIG. 2B, by increasing the resistance value R of the base-collector resistance element 23, the gain-output power characteristics can be made close to the gain-output power characteristics of the clamping circuit 20D of the comparative example with the four-stage configuration. In other words, it is possible to make the gain-output power characteristics of the three-stage clamping circuit 20 including one resistor-connected transistor 21 and two diodes 25 close to the gain-output power characteristics of the four-stage clamping circuit 20D. Reducing the number of stages of the clamping circuit 20 makes it possible to reduce the region occupied by the clamping circuit 20 on a substrate.

Here, multiple cascaded diodes may also be used in an electrostatic discharge (ESD) protection circuit for protecting an electronic circuit from electrostatic discharge. The ESD protection circuit does not require a function to finely adjust the limitation amount of radio frequency output power. The configuration of the clamping circuit according to the first embodiment is particularly suitable for a circuit aimed at improving the voltage withstand characteristics associated with changes in the load impedance of a radio frequency power amplifier.

Next, a variation of the first embodiment is described.

Diode-connected bipolar transistors may be used as the diodes 25 (FIG. 1A) of the clamping circuit 20 according to the first embodiment.

In the first embodiment (FIG. 1A), the diodes 25 are formed of layers that are the same as the base layer and the emitter layer of the transistor 22. However, the diodes 25 may instead be formed of layers that are the same as the base layer and the collector layer. In this case, the forward voltage Von of the resistor-connected transistor 21 does not match the forward voltage Von of the diodes 25. Also, diode-connected bipolar transistors, such as diode-connected HBTs, may also be used as the diodes 25. For example, a base-collector shorted HBT or an emitter-base shorted HBT may be used as each diode 25.

In the first embodiment, the clamping circuit 20 is constituted by one resistor-connected transistor 21 and two diodes 25. However, as described later in different embodiments, the number of resistor-connected transistors 21 may be two or more. Also, the number of diodes 25 may be one, three, or more. Furthermore, the clamping circuit 20 may be configured to not include the diodes 25 and formed only of multiple resistor-connected transistors 21.

### Second Embodiment

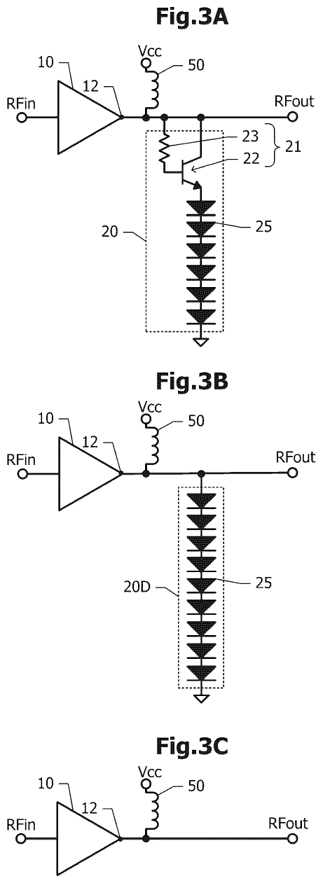

Next, a clamping circuit and an amplifier according to a second embodiment are described with reference to FIG. 3A to FIG. 6B. Below, descriptions are omitted for components that are the same as those of the clamping circuit 20 and the amplifier (FIG. 1A) according to the first embodiment.

FIG. 3A is an equivalent circuit diagram of a clamping circuit 20 and an amplifier according to the second embodiment. In the first embodiment (FIG. 1A), the clamping circuit 20 includes one resistor-connected transistor 21 and two diodes 25. In the second embodiment, the clamping circuit 20 includes one resistor-connected transistor 21 and six cascaded diodes 25.

FIG. 3B is an equivalent circuit diagram of a clamping circuit 20D and an amplifier according to a comparative example, and FIG. 3C is an equivalent circuit diagram of an amplifier according to another comparative example. In the comparative example illustrated in FIG. 3B, the clamping circuit 20D includes nine cascaded diodes 25 and includes no resistor-connected transistor. In the comparative example illustrated in FIG. 3C, no clamping circuit is connected to the output node 12 of the amplifier circuit 10.

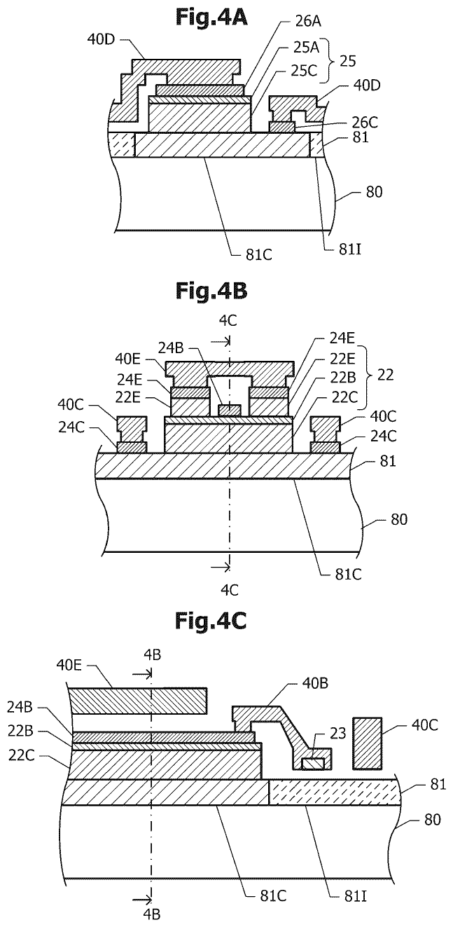

FIG. 4A is a cross-sectional view of a portion in which the diodes 25 included in the clamping circuit 20 of the second embodiment (FIG. 3A) are located. An epitaxial layer 81 is formed on a semiconductor substrate 80. The epitaxial layer 81 includes multiple conductive regions 81C and insulating element isolation regions 811 that surround the corresponding conductive regions 81C. Each of the diodes 25 includes a cathode layer 25C disposed on the corresponding one of the conductive regions 81C and an anode layer 25A disposed on the cathode layer 25C.

In addition to the cathode layer 25C, a cathode electrode 26C is disposed on the conductive region 81C. The cathode electrode 26C is electrically connected to the cathode layer 25C via the conductive region 81C. An anode electrode 26A is disposed on the anode layer 25A. The anode electrode 26A makes ohmic contact with the anode layer 25A. A first-layer wire 40D connects the cathode electrode 26 of one diode 25 to the anode electrode 26A of an adjacent diode 25.

FIGS. 4B and 4C are cross-sectional views of portions in which the resistor-connected transistor 21 (FIG. 3A) is located. As illustrated in FIG. 4B, the transistor 22 is disposed on the semiconductor substrate 80. The transistor 22 includes a collector layer 22C and a base layer 22B that are stacked on the corresponding one of the conductive regions 81C of the epitaxial layer 81, and two emitter mesas 22E that are spaced apart from each other on the base layer 22B.

In addition to the collector layer 22C, two collector electrodes 24C are arranged on the conductive region 81C to face each other across the collector layer 22C. The collector electrodes 24C are electrically connected to the collector layer 22C via the conductive region 81C. Emitter electrodes 24E are disposed on the two emitter mesas 22E. The emitter electrodes 24E are electrically connected to the emitter mesas 22E. A base electrode 24B is disposed on the base layer 22B. The base electrode 24B is electrically connected to the base layer 22B. In the cross section illustrated in FIG. 4B, a part of the base electrode 24B is disposed between the two emitter mesas 22E.

In the cross section of FIG. 4B, the collector electrode 24C may be provided only on one side of the collector layer 22C. In addition to the part of the base electrode 24B between the two emitter mesas 22E, another part of the base electrode 24B may also be disposed on the outer side of each of the two emitter mesas 22E. Also, only one emitter mesa 22E may be provided. In this case, a part of the base electrode 24B may be disposed on each side of the emitter mesa 22E, or a part of the base electrode 24B may be disposed on one side of the emitter mesa 22E.

A first-layer collector wire 40C is connected to the collector electrodes 24C. A first-layer emitter wire 40E is connected to the two emitter electrodes 24E.

FIG. 4C is a cross-sectional view taken along a dashed-dotted line 4C-4C in FIG. 4B. FIG. 4B corresponds to a cross-sectional view taken along a dashed-dotted line 4B-4B in FIG. 4C. The base-collector resistance element 23 is disposed on the element isolation region 811 via an interlayer insulating film (not shown). A first-layer base wire 40B connects the base electrode 24B to the base-collector resistance element 23. In addition to the base wire 40B, the first-layer collector wire 40C and the first-layer emitter wire 40E are provided.

Next, examples of materials of the components of the resistor-connected transistor 21 and the diodes 25 are described. A semi-insulating GaAs substrate is used as the semiconductor substrate 80. The conductive regions 81C of the epitaxial layer 81 are formed of n-type GaAs. The collector layer 22C and the cathode layer 25C are formed by patterning a common epitaxial layer comprised of n-type GaAs. The base layer 22B and the anode layer 25A are formed by patterning a common epitaxial layer comprised of p-type GaAs. Each emitter mesa 22E includes an n-type InGaP layer and an n-type GaAs layer on the n-type InGaP layer. A contact layer formed of n-type InGaAs may be disposed between the n-type GaAs layer and the emitter electrode 24E. Other semiconductor materials may also be used for these components. For example, a thin-film resistance material may be used for the base-collector resistance element 23.

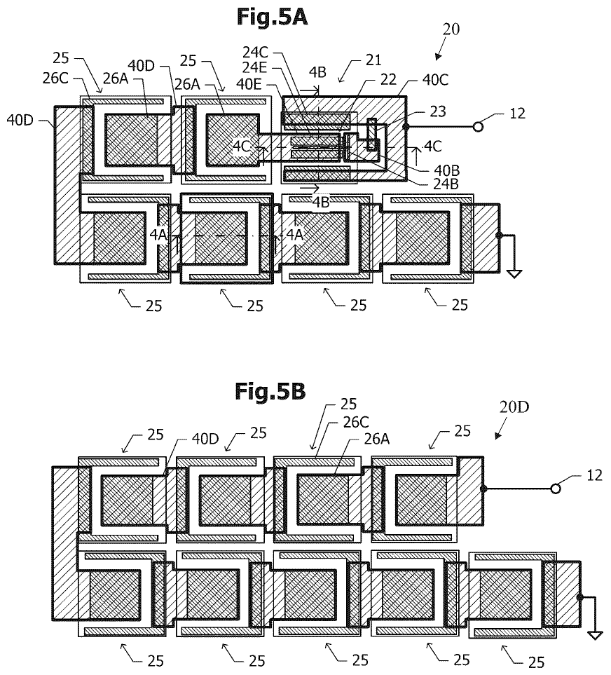

FIG. 5A is a diagram illustrating a positional relationship in plan view among components of the clamping circuit 20 according to the second embodiment. A row of one resistor-connected transistor 21 and six diodes 25 is folded at an intermediate point into two rows. One resistor-connected transistor 21 and two diodes 25 are included in one of the rows, and four diodes 25 are included in the other one of the rows. In FIG. 5A, downward-sloping relatively-dense hatching is applied to each of the collector electrodes 24C, the emitter electrodes 24E, the base electrode 24B, the anode electrodes 26A, and the cathode electrodes 26C. Each first-layer wire is represented by a relatively thick outline, and upward-sloping relatively-light hatching is applied to the first-layer wire.

The collector wire 40C having a U-shape overlaps each of the two collector electrodes 24C of the resistor-connected transistor 21 in plan view and is connected to the two collector electrodes 24C. In plan view, a part of the T-shaped base electrode 24B is disposed between the two emitter electrodes 24E. The base wire 40B overlaps a part of the base electrode 24B and is connected to the base electrode 24B at the overlapping position. One end of the base-collector resistance element 23 overlaps the collector wire 40C, the other end of the base-collector resistance element 23 overlaps the base wire 40B, and these ends are connected to the collector wire 40C and the base wire 40B at the overlapping positions. The emitter wire 40E overlaps the two emitter electrodes 24E and is connected to the emitter electrodes 24E at the overlapping positions.

The emitter wire 40E extends to a position at which the emitter wire 40E overlaps the anode electrode 26A of the adjacent diode 25 in the same row and is connected to the anode electrode 26A at the overlapping position. In plan view, the cathode electrode 26C of each diode 25 has a U-shape and surrounds the anode electrode 26A from three sides. The cathode electrode 26C may instead have a shape other than the U-shape in plan view. The wire 40D overlaps the cathode electrode 26C of one of two adjacent diodes 25 and the anode electrode 26A of the other one of the diodes 25 in plan view and is connected to the cathode electrode 26C and the anode electrode 26A at the overlapping positions.

The cathode electrode 26C of the diode 25 located at an end of the first row is connected via the wire 40D to the anode electrode 26A of the diode 25 located at an end of the second row. The cathode electrode 26C of the diode 25 located at the other end of the second row is connected to the ground potential. The collector wire 40C connected to the collector electrodes 24C of the resistor-connected transistor 21 is connected to the output node 12 (FIG. 3A) of the amplifier circuit 10.

FIG. 5B is a diagram illustrating a positional relationship in plan view among the components of the clamping circuit 20D according to the comparative example (FIG. 3B). A row of nine diodes 25 is folded at an intermediate point into two rows. The connection configuration of adjacent diodes 25 is the same as the connection configuration of two diodes 25 in the clamping circuit 20 (FIG. 5A) according to the second embodiment.

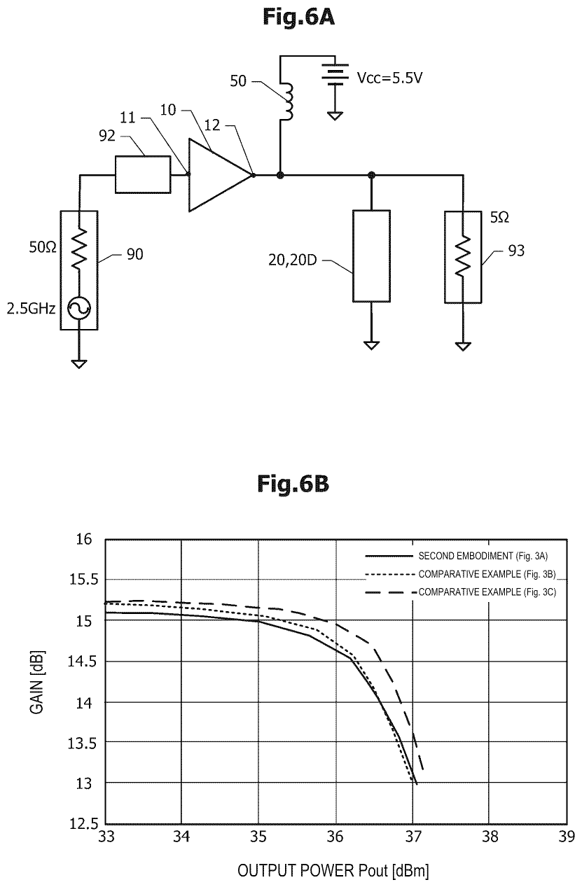

Next, the result of a simulation of the relationship between the gain and output power Pout of each of the amplifier including the clamping circuit 20 according to the second embodiment (FIG. 3A) and the amplifiers according to the comparative examples (FIGS. 3B and 3C) is described with reference to FIGS. 6A and 6B.

FIG. 6A is an equivalent circuit diagram of a circuit used for simulations. A radio frequency signal source 90 with output impedance of 50Ω is connected to the input node 11 of the amplifier circuit 10 via an impedance matching circuit 92. The clamping circuit 20 or 20D is connected to the output node 12 of the amplifier circuit 10. Also, a load 93 with impedance of 5Ω is connected to the output node 12. A GaAs/InGaP HBT is used for each of the transistors constituting the amplifier circuit 10 and the transistor 22 of the clamping circuit 20 (FIG. 3A). The element temperature during operation is set to 25° C. The resistance value R of the base-collector resistance element 23 (FIG. 3A) is set to 100Ω.

Radio frequency power (input power Pin) having a frequency of 2.5 GHz and generated by the radio frequency signal source 90 is varied within a range less than or equal to 30 dBm. The power supply voltage Vcc is set to 5.5 V. The base bias voltage of the HBTs constituting the amplifier circuit 10 is set to 1.3 V.

FIG. 6B is a graph showing a simulation result of the relationship between the gain and output power Pout of each of the amplifiers according to the second embodiment (FIG. 3A) and the comparative examples (FIGS. 3B and 3C). The horizontal axis represents the output power Pout in dBm, and the vertical axis represents the gain in dB. Here, the output power Pout is the power consumed by the load 93.

A solid line, a dotted line, and a long dashed line in the graph of FIG. 6B represent, respectively, the gain-output voltage characteristics of the amplifiers using the clamping circuits according to the second embodiment (FIG. 3A), the comparative example (FIG. 3B), and the other comparative example (FIG. 3C). As the input power Pin increases, the output power Pout increases. When the input power Pin exceeds a certain value, the gain starts to decrease, and the increase in the output power Pout is suppressed.

The graph indicates that almost the same output power limitation amount is obtained by the amplifier according to the comparative example (FIG. 3B) and the amplifier according to the second embodiment (FIG. 3A). In the second embodiment (FIG. 3A), the clamping circuit 20 with the seven-stage configuration is used. On the other hand, in the comparative example (FIG. 3B), the clamping circuit 20D with the nine-stage configuration is used. That is, almost the same output power limitation amount can be achieved with the clamping circuit 20 (FIG. 3A) even though the number of stages of the clamping circuit 20 is less than the number of stages of the clamping circuit 20D (FIG. 3B).

Next, advantageous effects of the second embodiment are described.

By using the resistor-connected transistor 21 as one of the clamping elements constituting the clamping circuit 20 as in the second embodiment (FIG. 3A, FIG. 5A), it is possible to reduce the number of clamping elements compared with the clamping circuit 20D (FIG. 3B, FIG. 5B) of the comparative example. This makes it possible to reduce the area of the region occupied by the clamping circuit 20 as illustrated in FIGS. 5A and 5B. FIG. 5A illustrates an example in which the multistage clamping circuit 20 is folded. However, when the number of stages of the clamping circuit 20 is small, the clamping circuit 20 may be laid out in a straight line without necessarily being folded.

Furthermore, similarly to the first embodiment, the output power limitation amount can be finely adjusted by adjusting the resistance value R of the base-collector resistance element 23 (FIG. 3A). This makes it possible to adjust the output power limitation amount such that the output power of the amplifier circuit 10 meets the required output without necessarily exceeding the breakdown limit.

### Third Embodiment

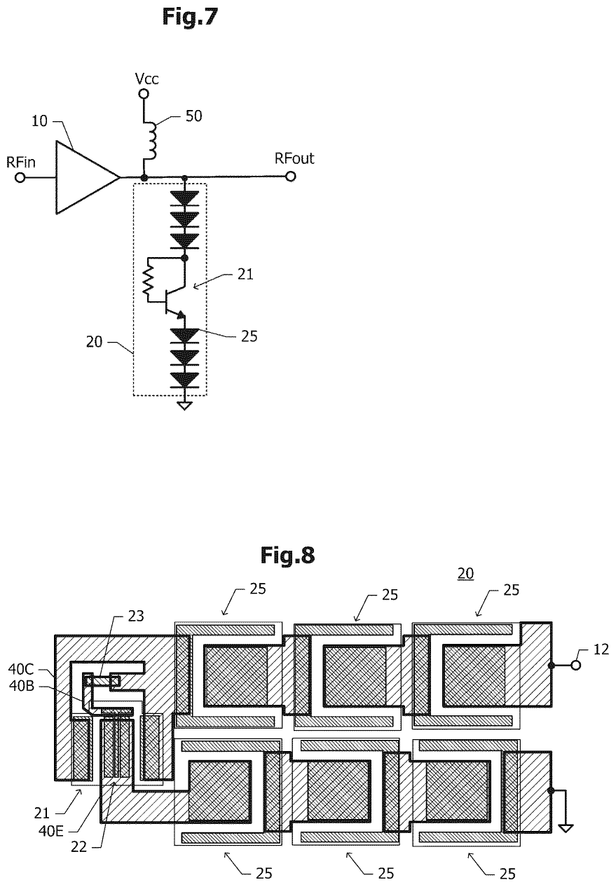

Next, a clamping circuit and an amplifier according to a third embodiment are described with reference to FIGS. 7, 8, and 9. Below, descriptions are omitted for components that are the same as those of the clamping circuit and the amplifier (FIG. 3A) according to the second embodiment.

FIG. 7 is an equivalent circuit diagram of a clamping circuit 20 and an amplifier according to the third embodiment. In the second embodiment (FIG. 3A), the resistor-connected transistor 21 is connected to an end of the multistage clamping circuit 20 that is closer to the output node 12. In the third embodiment, the resistor-connected transistor 21 is connected at an intermediate point of the multistage clamping circuit 20. For example, the resistor-connected transistor 21 is connected in the middle of the multistage clamping circuit 20. That is, the number of diodes 25 disposed closer to the output node 12 than the resistor-connected transistor 21 is the same as the number of diodes 25 disposed closer to the ground potential.

FIG. 8 is a diagram illustrating the arrangement in plan view of the resistor-connected transistor 21 and multiple diodes 25 constituting the clamping circuit 20 according to the third embodiment. The configuration of each of the resistor-connected transistor 21 and the multiple diodes 25 is the same as that of the clamping circuit 20 according to the second embodiment (FIG. 5A).

Six diodes 25 are arranged in two rows, and the diode 25 disposed at an end of one of the rows is connected to the diode 25 disposed at the same side end of the other one of the rows via the resistor-connected transistor 21. That is, a row of multiple clamping elements constituting the clamping circuit 20 is folded at an intermediate point, and the resistor-connected transistor 21 is disposed at the folded point.

FIG. 9 is a graph showing a simulation result of the relationship between the gain and output power Pout of each of the amplifiers according to the third embodiment (FIG. 7) and the comparative examples (FIGS. 3B and 3C). The horizontal axis represents the output power Pout in dBm, and the vertical axis represents the gain in dB. A solid line, a dotted line, and a long dashed line in the graph of FIG. 9 represent, respectively, the gain-output voltage characteristics of the amplifiers using the clamping circuits according to the third embodiment (FIG. 7), the comparative example (FIG. 3B), and the other comparative example (FIG. 3C). The amplifier according to the third embodiment has substantially the same characteristics as the relationship between the gain and output power Pout of the amplifier according to the second embodiment.

Next, advantageous effects of the third embodiment are described.

With the third embodiment, similarly to the second embodiment, the output power limitation amount can be finely adjusted by adjusting the resistance value R of the base-collector resistance element 23 (FIG. 3A). This makes it possible to adjust the output power limitation amount such that the output power meets the required output without necessarily exceeding the breakdown limit of the amplifier circuit 10.

Furthermore, with the third embodiment, because the resistor-connected transistor 21 is disposed at the folded point of the clamping circuit 20, the symmetry of the planar arrangement of the multiple diodes 25 and the resistor-connected transistor 21 is improved, and the area of the region occupied by the clamping circuit 20 can be reduced.

Next, a variation of the third embodiment is described.

In the third embodiment, the resistor-connected transistor 21 is connected in the middle of the multistage clamping circuit 20. However, the resistor-connected transistor 21 may also be disposed in any other position.

### Fourth Embodiment

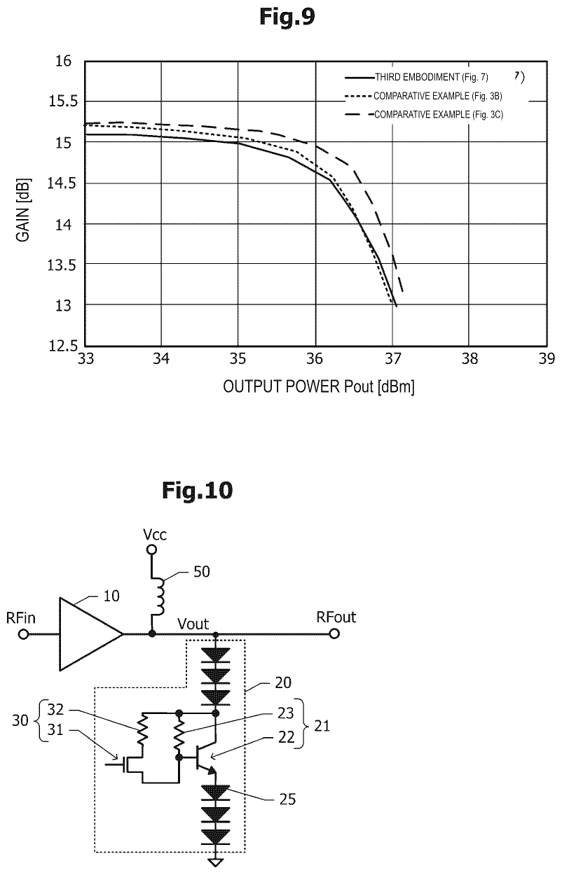

Next, a clamping circuit and an amplifier according to a fourth embodiment are described with reference to FIG. 10. Below, descriptions are omitted for components that are the same as those of the clamping circuit 20 and the amplifier of the third embodiment described with reference to FIGS. 7, 8, and 9.

FIG. 10 is an equivalent circuit diagram of a clamping circuit 20 and an amplifier according to the fourth embodiment. In the clamping circuit 20 according to the third embodiment (FIG. 7), the base-collector resistance element 23 with a fixed resistance value R is connected between the base and the collector of the resistor-connected transistor 21, and the base-collector resistance is a fixed value. In contrast, in the fourth embodiment, a resistance variable circuit 30 is connected in parallel with the base-collector resistance element 23. The resistance variable circuit 30 includes a resistance element 32 and a switch element 31 that are connected in series with each other. For example, similarly to the base-collector resistance element 23, a thin-film resistance material is used for the resistance element 32. For example, a MOSFET is used for the switch element 31.

When the switch element 31 is turned on and off, the resistance value between the base and the collector of the resistor-connected transistor 21 changes. When the resistance value between the base and the collector of the resistor-connected transistor 21 changes, the clamp current-output voltage characteristics change as shown in FIG. 2A, and as a result, the gain-output power characteristics change.

Next, advantageous effects of the fourth embodiment are described.

With the fourth embodiment, the output power limitation amount can be adjusted more finely compared to the third embodiment by adjusting the value of the base-collector resistance of the resistor-connected transistor 21. This makes it possible to adjust the output power limitation amount such that the output power meets the required output without necessarily exceeding the breakdown limit of the amplifier circuit 10.

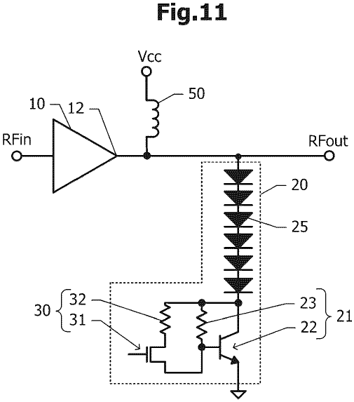

Next, a variation of the fourth embodiment is described with reference to FIG. 11.

FIG. 11 is an equivalent circuit diagram of a clamping circuit 20 and an amplifier according to a variation of the fourth embodiment. In the fourth embodiment (FIG. 10), the resistor-connected transistor 21 is connected at an intermediate point of the multistage clamping circuit 20. In contrast, in the variation illustrated in FIG. 11, the resistor-connected transistor 21 is connected to an end of the clamping circuit 20 closer to the ground potential.

There is parasitic capacitance between each interconnection point of clamping elements of the clamping circuit 20 and the ground potential. Due to the parasitic capacitance, in a state in which no electric current flows through the clamping circuit 20, the voltage applied to each of the diodes 25 and the resistor-connected transistor 21 gradually decreases from a stage near the output node 12 toward a stage near the ground potential. Accordingly, when the resistor-connected transistor 21 is connected to an end closer to the ground potential, the voltage applied to the switch element 31 becomes smaller compared to a configuration in which the resistor-connected transistor 21 is connected at a position closer to the output node 12 of the amplifier circuit 10. This makes it possible to reduce the size of the switch element 31.

Next, another variation of the fourth embodiment is described.

In the fourth embodiment, the resistance variable circuit 30 is constituted by the switch element 31 and the resistance element 32 that are connected in series with each other. However, the resistance variable circuit 30 may be constituted only by the switch element 31. In this case, when the switch element 31 is turned on, the base and the collector of the resistor-connected transistor 21 are short-circuited, and the resistor-connected transistor 21 comes to have the same current-voltage characteristics as the diodes 25.

In the fourth embodiment, a single-pole single-throw (SPST) switch is used as the switch element 31. However, a single-pole multi-throw (SPnT) switch may instead be used as the switch element 31, and resistance elements with different resistance values may be connected to the multiple contacts of the SPnT switch. This configuration makes it possible to more finely change the resistance value between the base and the collector of the resistor-connected transistor 21.

The resistance variable circuit 30 may be connected in series with the base-collector resistance element 23. In this case, the resistance variable circuit 30 may be comprised of a resistance element and a switch element that are connected in parallel with each other. Even with this configuration, it is possible to change the resistance value between the base and the collector of the resistor-connected transistor 21 by turning the switch element on and off.

### Fifth Embodiment

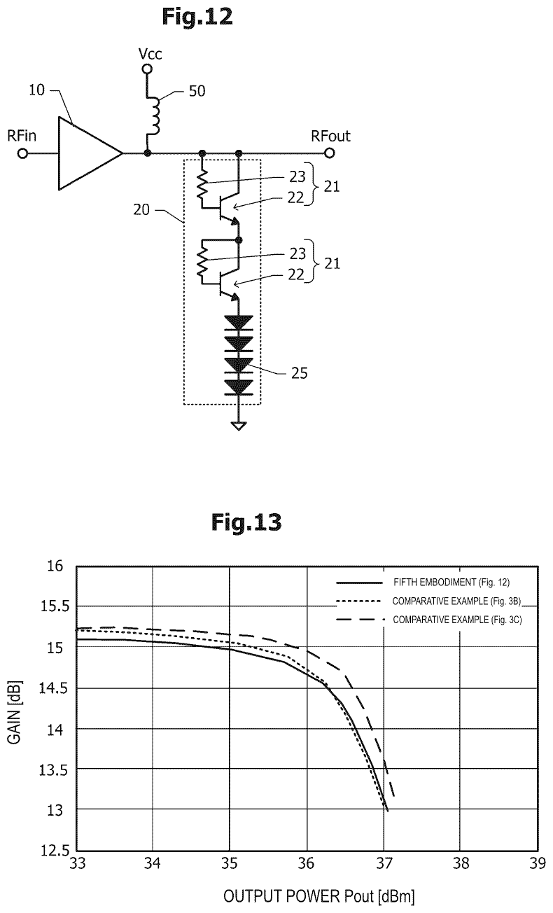

Next, a clamping circuit and an amplifier according to a fifth embodiment are described with reference to FIGS. 12 and 13. Below, descriptions are omitted for components that are the same as those of the clamping circuit 20 and the amplifier of the second embodiment described with reference to FIG. 3A and FIGS. 4A to 5A.

FIG. 12 is an equivalent circuit diagram of a clamping circuit 20 and an amplifier according to the fifth embodiment. The clamping circuit 20 of the second embodiment (FIG. 3A) has a configuration in which one resistor-connected transistor 21 and six diodes 25 are cascaded. In contrast, the clamping circuit 20 according to the fifth embodiment has a configuration in which two resistor-connected transistors 21 and four diodes 25 are cascaded.

FIG. 13 is a graph showing a simulation result of the relationship between the gain and output power Pout of each of the amplifiers according to the fifth embodiment (FIG. 12) and the comparative examples (FIGS. 3B and 3C). The horizontal axis represents the output power Pout in dBm, and the vertical axis represents the gain in dB. A solid line, a dotted line, and a long dashed line in the graph of FIG. 13 represent, respectively, the gain-output voltage characteristics of the amplifiers using the clamping circuits according to the fifth embodiment (FIG. 12), the comparative example (FIG. 3B), and the other comparative example (FIG. 3C). The resistance value R of the base-collector resistance element 23 (FIG. 12) of each of the two resistor-connected transistors 21 is set to 100Ω. When the input power Pin exceeds a certain value, the gain starts to decrease, and the increase in the output power Pout is suppressed. The graph indicates that almost the same output power limitation amount is obtained by the amplifier according to the comparative example (FIG. 3B) and the amplifier according to the fifth embodiment (FIG. 12).

Next, advantageous effects of the fifth embodiment are described.

While the clamping circuit 20D of the comparative example (FIG. 3B) has a nine-stage configuration, the clamping circuit 20 of the fifth embodiment has a six-stage configuration. Thus, the fifth embodiment makes it possible to achieve an output power limitation amount that is substantially the same as the output power limitation amount achieved by the clamping circuit 20D of the comparative example (FIG. 3B) with fewer stages. This makes it possible to reduce the region occupied by the clamping circuit 20 on the substrate.

Also, the number of stages of the clamping circuit 20 is even less than that of the clamping circuit 20 according to the second embodiment (FIG. 3A). Accordingly, the region occupied by the clamping circuit 20 on the substrate can be made smaller than the region occupied by the clamping circuit 20 according to the second embodiment (FIG. 3A).

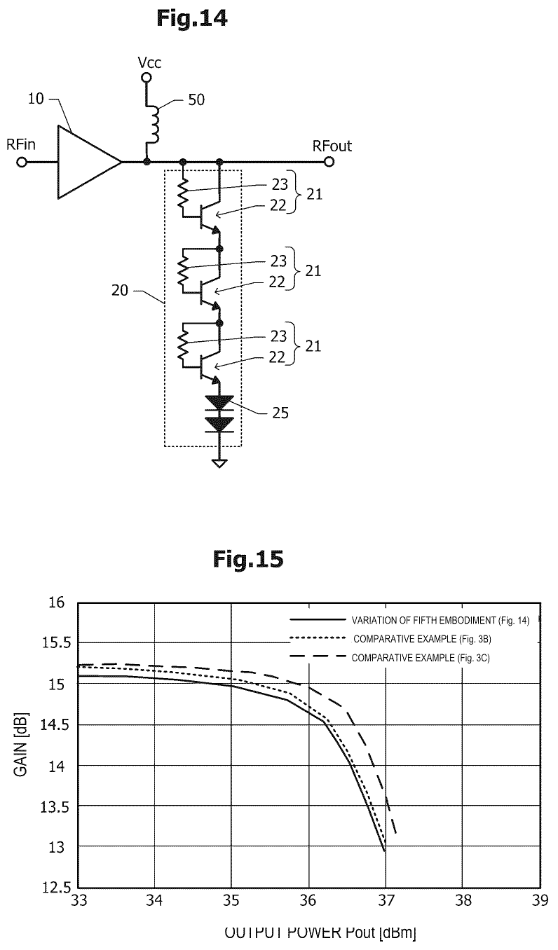

Next, a clamping circuit and an amplifier according to a variation of the fifth embodiment are described with reference to FIGS. 14 and 15.

FIG. 14 is an equivalent circuit diagram of a clamping circuit 20 and an amplifier according to a variation of the fifth embodiment. The clamping circuit 20 according to the fifth embodiment (FIG. 12) has a configuration in which two resistor-connected transistors 21 and four diodes 25 are cascaded. In contrast, the clamping circuit 20 according to the variation of the fifth embodiment illustrated in FIG. 14 has a configuration in which three resistor-connected transistors 21 and two diodes 25 are cascaded.

FIG. 15 is a graph showing a simulation result of the relationship between the gain and output power Pout of each of the amplifiers according to the variation of the fifth embodiment (FIG. 14) and the comparative examples (FIGS. 3B and 3C). The horizontal axis represents the output power Pout in dBm, and the vertical axis represents the gain in dB. A solid line, a dotted line, and a long dashed line in the graph of FIG. 15 represent, respectively, the gain-output voltage characteristics of the amplifiers using the clamping circuits according to the variation of the fifth embodiment (FIG. 14), the comparative example (FIG. 3B), and the other comparative example (FIG. 3C). The resistance values R of the base-collector resistance element 23 of each of the three resistor-connected transistors 21 according to the variation of the fifth embodiment is set to 100Ω.

The graph indicates that the amplifier according to the variation of the fifth embodiment (FIG. 14) also achieves almost the same output power limitation amount as that achieved by the amplifier according to the comparative example (FIG. 3B). While the clamping circuit 20 according to the fifth embodiment (FIG. 12) has a six-stage configuration, the clamping circuit 20 according to the variation illustrated in FIG. 14 has a five-stage configuration. Accordingly, the clamping circuit 20 according to the variation illustrated in FIG. 14 occupies an even smaller area compared to the fifth embodiment.

Next, another variation of the fifth embodiment is described.

In the simulations (FIGS. 13 and 15) in the fifth embodiment and its variation, the resistance values R of the base-collector resistance elements 23 of all resistor-connected transistors 21 included in the clamping circuit 20 are set to the same value. As another variation, the resistance values R of the base-collector resistance elements 23 of multiple resistor-connected transistors 21 included in the clamping circuit 20 may be set to different values. Using different resistance values R makes it possible to more finely adjust the output power limitation amount.

In the fifth embodiment (FIG. 12) and its variation (FIG. 14), the clamping circuit 20 includes at least one diode 25. As another variation, the clamping circuit 20 may include multiple cascaded resistor-connected transistors 21 and no diode 25. Also, the number of resistor-connected transistors 21 and the number of diodes 25 constituting the clamping circuit 20 may be adjusted according to a desired output power limitation amount.

### Sixth Embodiment

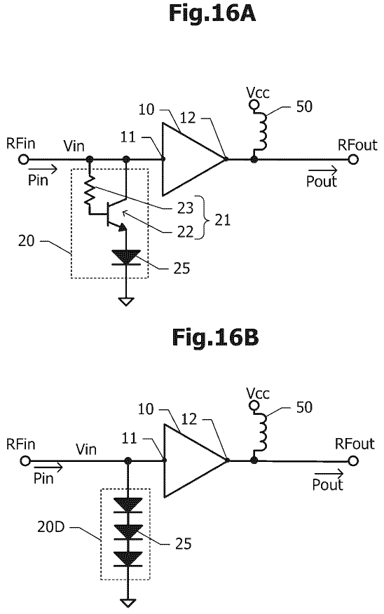

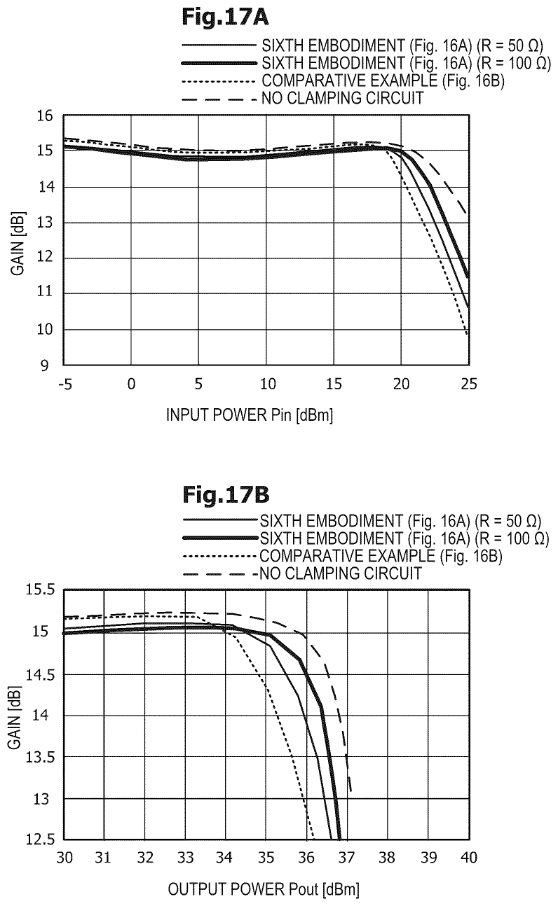

Next, a clamping circuit and an amplifier according to a sixth embodiment are described with reference to FIGS. 16A to 17B. Below, descriptions are omitted for components that are the same as those of the clamping circuit 20 and the amplifier according to the first embodiment (FIG. 1A).

FIG. 16A is an equivalent circuit diagram of a clamping circuit 20 and an amplifier according to the sixth embodiment. In the first embodiment (FIG. 1A), the clamping circuit 20 is connected between the output node 12 of the amplifier circuit 10 and the ground potential. In contrast, in the sixth embodiment, the clamping circuit 20 is connected between the input node 11 of the amplifier circuit 10 and the ground potential.

Similarly to the clamping circuit 20 according to the first embodiment (FIG. 1A), the clamping circuit 20 includes the resistor-connected transistor 21 and the diode 25 that are cascaded. For example, one resistor-connected transistor 21 and one diode 25 are connected in series with each other.

When an input voltage Vin (the voltage at the input node 11) exceeds the clamp voltage of the clamping circuit 20, the clamping circuit 20 becomes conductive.

Accordingly, when the power (the input power Pin) of the radio frequency signal RFin input from the preceding amplifier circuit increases, a clamp current starts to flow through the clamping circuit 20. As a result, the power input to the input node 11 of the amplifier circuit 10 decreases. The clamping circuit 20 connected between the input node 11 of the amplifier circuit 10 and the ground potential has a function to limit the power of a radio frequency signal input to the input node 11 of the amplifier circuit 10.

FIG. 16B is an equivalent circuit diagram of a clamping circuit 20 and an amplifier according to a comparative example. In the comparative example illustrated in FIG. 16B, the clamping circuit 20D connected to the input node 11 of the amplifier circuit 10 is constituted only by multiple, for example, three, cascaded diodes 25, and no resistor-connected transistor 21 is connected.

FIG. 17A is a graph showing simulation results of the relationship between the input power Pin and gain, and FIG. 17B is a graph showing simulation results of the relationship between the output power Pout and gain. The horizontal axis in FIG. 17A represents the input power Pin in dBm, and the horizontal axis in FIG. 17B represents the output power Pout in dBm. The vertical axis in each of FIGS. 17A and 17B represents gain in dB. Here, “gain” indicates the ratio of the output power Pout to the input power Pin (or the difference between them in dB). The frequency of the radio frequency signal RFin is set to 2.5 GHz, and the input power Pin is varied within a range less than or equal to 30 dBm. The power supply voltage Vcc of the amplifier circuit 10 is set to 5.5 V. The base bias voltage of the HBTs constituting the amplifier circuit 10 is set to 1.3 V.

A thin solid line and a thick solid line in each of the graphs of FIGS. 17A and 17B indicate, respectively, gains obtained when the resistance value R of the base-collector resistance element 23 of the clamping circuit 20 according to the sixth embodiment (FIG. 16A) is set to 50Ω and 100Ω. A dotted line indicates gain obtained when the clamping circuit 20D of the comparative example (FIG. 16B) is connected, and a long dashed line indicates gain obtained when no clamping circuit is connected. When the input power Pin is increased, the radio frequency power input to the input node 11 of the amplifier circuit 10 is limited.

As shown in FIG. 17A, when the radio frequency power input to the input node 11 is limited, in a range in which the input power Pin is greater than or equal to about 23 dBm, the gain becomes lower compared to the case in which no clamping circuit is connected. The amount of gain reduction is smallest in the case where no clamping circuit is connected and is largest in the case of the comparative example (FIG. 16B). The amount of gain reduction in the case of the sixth embodiment is between the above two cases, and the amount of gain reduction achieved when the resistance value R of the base-collector resistance element 23 is set to 100Ω is smaller than that achieved when the resistance value R is set to 50Ω.

As shown in FIG. 17B, when the clamping circuit 20 or the clamping circuit 20D is connected to the input node 11, the output power Pout is limited compared to the case in which no clamping circuit is connected. The output power limitation amount achieved by the comparative example (FIG. 16B) is greater than that achieved by the sixth embodiment (FIG. 16A). In the sixth embodiment (FIG. 16A), the output power limitation amount increases as the resistance value R of the base-collector resistance element 23 decreases.

Next, advantageous effects of the sixth embodiment are described.

Connecting the clamping circuit 20 to the input node 11 of the amplifier circuit 10 as in the sixth embodiment makes it possible to limit the output power Pout. This prevents the amplifier circuit 10 from operating beyond the breakdown limit. Also, the limitation amount of the output power Pout can be finely adjusted by adjusting the resistance value R of the base-collector resistance element 23 of the resistor-connected transistor 21 included in the clamping circuit 20. This in turn makes it possible to adjust the limitation amount of the output power Pout such that the output power meets a required output without necessarily exceeding the breakdown limit.

To achieve, by using only diodes 25, an output power limitation amount that is substantially the same as that achieved by the clamping circuit 20 including the base-collector resistance element 23 whose resistance value R is set to 100Ω, the clamping circuit 20D (FIG. 16B) needs to have a multistage configuration with more than three stages. The sixth embodiment makes it possible to achieve an output power limitation amount, which is equivalent to that achieved by the multistage clamping circuit 20D with more than three stages, by using the clamping circuit 20 with a two-stage configuration. This in turn makes it possible to reduce the region occupied by the clamping circuit 20 on the substrate.

Next, a variation of the sixth embodiment is described.

The clamping circuit 20 according to the sixth embodiment (FIG. 16A) includes the resistor-connected transistor 21 and the diode 25. However, the clamping circuit 20 may be constituted by multiple resistor-connected transistors 21 and no diode 25.

### Seventh Embodiment

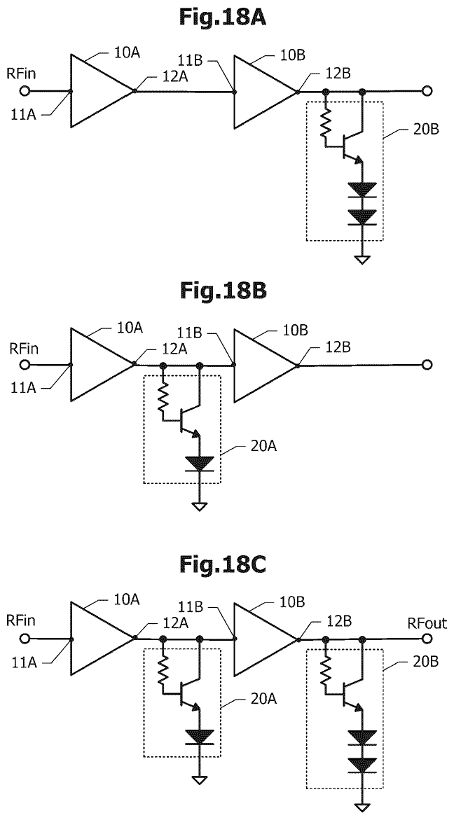

Next, an amplifier according to a seventh embodiment is described with reference to FIG. 18A. The amplifier according to the seventh embodiment uses the clamping circuit 20 according to one of the first through sixth embodiments.

FIG. 18A is an equivalent circuit diagram of the amplifier according to the seventh embodiment. The amplifier according to the seventh embodiment includes an initial-stage amplifier circuit 10A and an output-stage amplifier circuit 10B. In each of the first through sixth embodiments, the clamping circuit 20 is connected to either the input node 11 or the output node 12 of one amplifier circuit 10. In the seventh embodiment, a clamping circuit 20B is connected to an output node 12B of the output-stage amplifier circuit 10B of a two-stage amplifier. Here, an impedance matching circuit is normally inserted between the initial-stage amplifier circuit 10A and the output-stage amplifier circuit 10B. However, in FIG. 18A, the illustration of the impedance matching circuit is omitted. The same applies to FIGS. 18B and 18C.

The clamping circuit 20B has the same configuration as the clamping circuit 20 according to one of the first embodiment (FIG. 1A), the second embodiment (FIG. 3A), the third embodiment (FIG. 7), the fourth embodiment (FIG. 10), the fifth embodiment (FIG. 12), and the variations of these embodiments.

FIGS. 18B and 18C are equivalent circuit diagrams of amplifiers according to variations of the seventh embodiment.

In the variation illustrated in FIG. 18B, a clamping circuit 20A is connected between the initial-stage amplifier circuit 10A and the output-stage amplifier circuit 10B. The clamping circuit 20A has the same configuration as the clamping circuit 20 according to the sixth embodiment (FIG. 16A) or its variation. An inter-stage impedance matching circuit may be inserted between an output node 12A of the initial-stage amplifier circuit 10A and the clamping circuit 20A, or may be connected between the clamping circuit 20A and an input node 11B of the output-stage amplifier circuit 10B. Also, an impedance matching circuit may be inserted at each of the above positions.

The suitable level of the voltage (clamp voltage) with which the clamping circuit 20A becomes conductive varies depending on the position at which the impedance matching circuit is inserted. The clamping circuit 20A may be designed according to the clamp voltage required for the clamping circuit 20A.

In the variation illustrated in FIG. 18C, the clamping circuit 20A is connected between the initial-stage amplifier circuit 10A and the output-stage amplifier circuit 10B, and the other clamping circuit 20B is connected to the output node 12B of the output-stage amplifier circuit 10B. The number of stages of the clamping circuit 20B is greater than the number of stages of the clamping circuit 20A.

Next, advantageous effects of the seventh embodiment are described.

As in the seventh embodiment, even in a two-stage amplifier, the output power limitation amount can be finely adjusted by connecting a clamping circuit to a node between the initial-stage amplifier circuit 10A and the output-stage amplifier circuit 10B or to the output node 12B of the output-stage amplifier circuit 10B. This makes it possible to adjust the output power limitation amount such that the output power of the output-stage amplifier circuit 10B meets the required output without necessarily exceeding the breakdown limit.

The number of stages of the clamping circuit 20A connected between stages as illustrated in FIG. 18B is less than the number of stages of the clamping circuit 20B that is connected to the output node 12B of the output-stage amplifier circuit 10B as illustrated in FIG. 18A. This makes it possible to reduce the region occupied by the clamping circuit on the substrate.

Connecting the clamping circuits 20A and 20B to two nodes as illustrated in FIG. 18C makes it possible to enhance the effect of preventing the output power of the output-stage amplifier circuit 10B from exceeding the breakdown limit.

Connecting a clamping circuit to the input node 11A of the initial-stage amplifier circuit 10A does not provide a substantial clamping effect. Thus, the clamping circuit can be connected to at least one of the node between the initial-stage amplifier circuit 10A and the output-stage amplifier circuit 10B and the output node 12B of the output-stage amplifier circuit 10B.

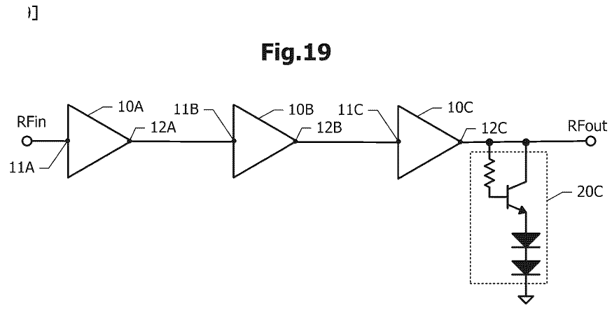

Next, other variations of the seventh embodiment are described with reference to FIGS. 19 to 21C. FIGS. 19 to 21C are equivalent circuit diagrams of amplifiers according to variations of the seventh embodiment. While the amplifier according to the seventh embodiment has a two-stage configuration, each of the amplifiers according to the variations of the seventh embodiment illustrated in FIGS. 19 to 21C has a three-stage configuration and includes an initial-stage amplifier circuit 10A, a middle-stage amplifier circuit 10B, and an output-stage amplifier circuit 10C. In these figures, the illustration of impedance matching circuits is omitted.

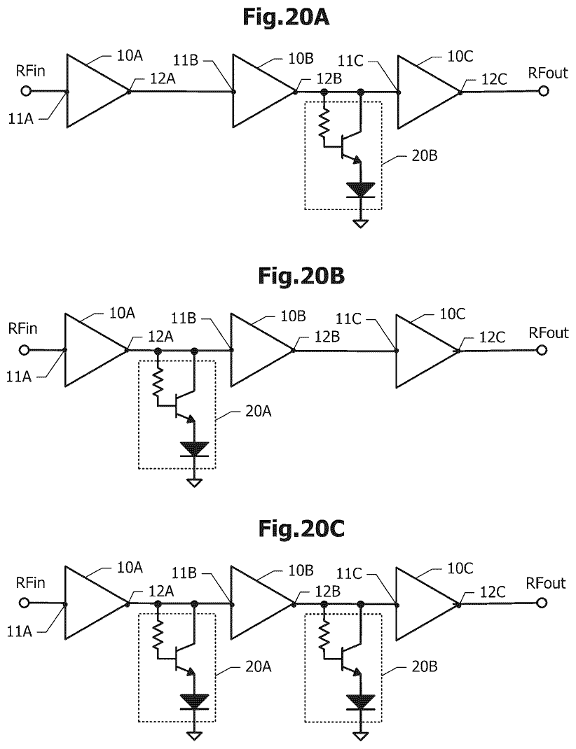

In the variation illustrated in FIG. 19, a clamping circuit 20C is connected to an output node 12C of the output-stage amplifier circuit 10C. In the variation illustrated in FIG. 20A, the clamping circuit 20B is connected between the middle-stage amplifier circuit 10B and the output-stage amplifier circuit 10C. In the variation illustrated in FIG. 20B, the clamping circuit 20A is connected between the initial-stage amplifier circuit 10A and the middle-stage amplifier circuit 10B. In the variation illustrated in FIG. 20C, the clamping circuit 20A is connected between the initial-stage amplifier circuit 10A and the middle-stage amplifier circuit 10B, and the clamping circuit 20B is connected between the middle-stage amplifier circuit 10B and the output-stage amplifier circuit 10C.

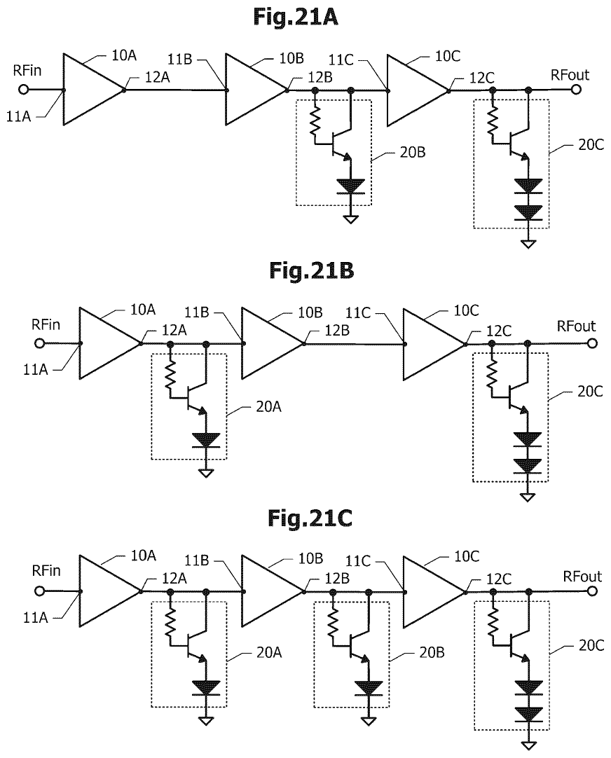

In each of the variations illustrated in FIGS. 21A, 21B, and 21C, the clamping circuit 20C is additionally connected to the output node 12C of the output-stage amplifier circuit 10C of the corresponding one of the amplifiers according to the variations illustrated in FIGS. 20A, 20B, and 20C.

Even with the three-stage amplifiers illustrated in FIGS. 19 to 21C, it is possible to perform output power limitation for the output-stage amplifier circuit 10C by connecting one of the clamping circuits 20A, 20B, and 20C to at least one node other than the input node 11A of the initial-stage amplifier circuit 10A. The output power limitation amount can be finely adjusted by including the resistor-connected transistor 21 in each of the clamping circuits 20A, 20B, and 20C as in the clamping circuit 20 of, for example, the first embodiment.

### Eighth Embodiment

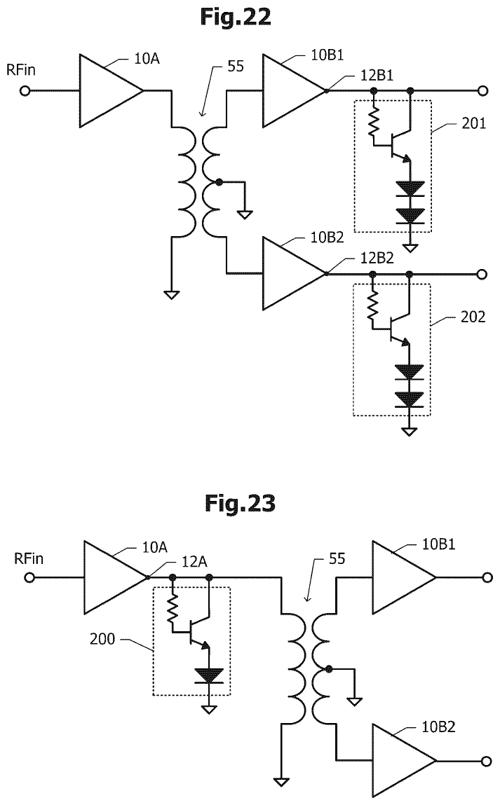

Next, an amplifier according to an eighth embodiment is described with reference to FIG. 22. The amplifier according to the eighth embodiment uses the clamping circuit 20 according to one of the first through sixth embodiments.

FIG. 22 is an equivalent circuit diagram of the amplifier according to the eighth embodiment. In each of the amplifiers according to the first through sixth embodiments, both of the input signal and the output signal are single-ended signals. In contrast, the amplifier according to the eighth embodiment includes an initial-stage amplifier circuit 10A and output-stage amplifier circuits 10B1 and 10B2, and the amplifier circuits 10B1 and 10B2 constitute a differential amplifier circuit. The radio frequency signal RFin, which is a single-ended signal, is input to the initial-stage amplifier circuit 10A. A balanced-unbalanced conversion circuit 55 converts a radio frequency signal output from the amplifier circuit 10A into differential signals.

One of the differential signals output from the balanced-unbalanced conversion circuit 55 is input to the amplifier circuit 10B1, and the other one of the differential signals is input to the amplifier circuit 10B2. A clamping circuit 201 is connected between an output node 12B1 of the amplifier circuit 10B1 and the ground potential, and another clamping circuit 202 is connected between an output node 12B2 of the amplifier circuit 10B2 and the ground potential. Each of the clamping circuits 201 and 202 is implemented by, for example, the clamping circuit 20 according to one of the first embodiment (FIG. 1A), the second embodiment (FIG. 3A), the third embodiment (FIG. 7), the fourth embodiment (FIG. 10), the fifth embodiment (FIG. 12), and the variations of these embodiments.

When the output voltage of the amplifier circuit 10B1 becomes greater than or equal to the clamp voltage of the clamping circuit 201, the output power of the amplifier circuit 10B1 is limited. When the output voltage of the amplifier circuit 10B2 becomes greater than or equal to the clamp voltage of the clamping circuit 202, the output power of the amplifier circuit 10B2 is limited.

Next, advantageous effects of the eighth embodiment are described.

By using the clamping circuit 20 according to any one of the first embodiment (FIG. 1A), the second embodiment (FIG. 3A), the third embodiment (FIG. 7), the fourth embodiment (FIG. 10), the fifth embodiment (FIG. 12), and the variations of these embodiments in the differential amplifier circuit, the output power limitation amount can be finely adjusted even in the differential amplifier circuit as in the first embodiment and other embodiments. This makes it possible to adjust the output power limitation amount such that the output power of the output-stage amplifier circuits 10B1 and 10B2 meets the required output without necessarily exceeding the breakdown limit.

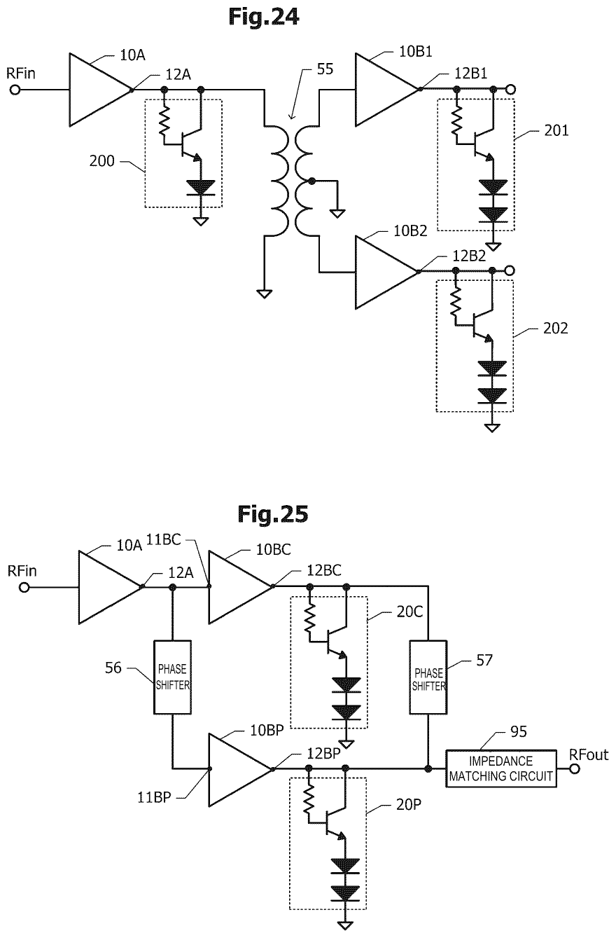

Next, variations of the eighth embodiment are described with reference to FIGS. 23 and 24. FIGS. 23 and 24 are equivalent circuit diagrams of amplifiers according to variations of the eighth embodiment.

As in the variation illustrated in FIG. 23, a clamping circuit 200 may be connected between the output node 12A of the initial-stage amplifier circuit 10A and the balanced-unbalanced conversion circuit 55. For example, the clamping circuit 200 has the same configuration as the clamping circuit 20 according to the sixth embodiment (FIG. 16A). The power of the single-ended signal to be input to the balanced-unbalanced conversion circuit 55 is limited by the clamping circuit 200. As a result, the power of the differential signals input to the output-stage amplifier circuits 10B1 and 10B2 is limited.

As in the variation illustrated in FIG. 24, the clamping circuit 200 may be connected between the output node 12A of the initial-stage amplifier circuit 10A and the balanced-unbalanced conversion circuit 55, and the clamping circuits 201 and 202 may be connected to the output nodes 12B1 and 12B2 of the output-stage amplifier circuits 10B1 and 10B2, respectively.

### Ninth Embodiment

Next, an amplifier according to a ninth embodiment is described with reference to FIG. 25. The amplifier according to the ninth embodiment uses the clamping circuit 20 according to one of the first through sixth embodiments.

FIG. 25 is an equivalent circuit diagram of the amplifier according to the ninth embodiment. The amplifier according to the ninth embodiment includes an initial-stage amplifier circuit 10A and output-stage amplifier circuits 10BC and 10BP. The amplifier circuits 10BC and 10BP constitute a Doherty amplifier circuit, and the amplifier circuits 10BC and 10BP are biased to operate as a carrier amplifier and a peak amplifier, respectively.

An output node 12A of the initial-stage amplifier circuit 10A is connected to an input node 11BC of the amplifier circuit 10BC and is also connected to an input node 11BP of the amplifier circuit 10BP via a phase shifter 56. An output node 12BP of the amplifier circuit 10BP is connected to an impedance matching circuit 95, and an output node 12BC of the amplifier circuit 10BC is connected to the impedance matching circuit 95 via a phase shifter 57. For example, each of the phase shifters 56 and 57 delays the phase of a radio frequency signal by 90°. A radio frequency signal RFout is output from the impedance matching circuit 95.

A clamping circuit 20C is connected between the output node 12BC of the amplifier circuit 10BC, which operates as a carrier amplifier, and the ground potential. A clamping circuit 20P is connected between the output node 12BP of the amplifier circuit 10BP, which operates as a peak amplifier, and the ground potential. For example, each of the clamping circuits 20C and 20P is implemented by the clamping circuit 20 according to any one of the first embodiment (FIG. 1A), the second embodiment (FIG. 3A), the third embodiment (FIG. 7), the fourth embodiment (FIG. 10), the fifth embodiment (FIG. 12), and the variations of these embodiments.

The clamping circuits 20C and 20P, respectively, limit the output power of the amplifier circuit 10BC operating as a carrier amplifier and the amplifier circuit 10BP operating as a peak amplifier.

Next, advantageous effects of the ninth embodiment are described.

In the ninth embodiment, each of the clamping circuits 20C and 20P is implemented by the clamping circuit 20 according to any one of the first embodiment (FIG. 1A), the second embodiment (FIG. 3A), the third embodiment (FIG. 7), the fourth embodiment (FIG. 10), the fifth embodiment (FIG. 12), and the variations of these embodiments. Accordingly, the ninth embodiment makes it possible to finely adjust the output power limitation amount. This makes it possible to adjust the output power limitation amount such that the output power of each of the output-stage amplifier circuits 10BC and 10BP meets the required output without necessarily exceeding the breakdown limit.

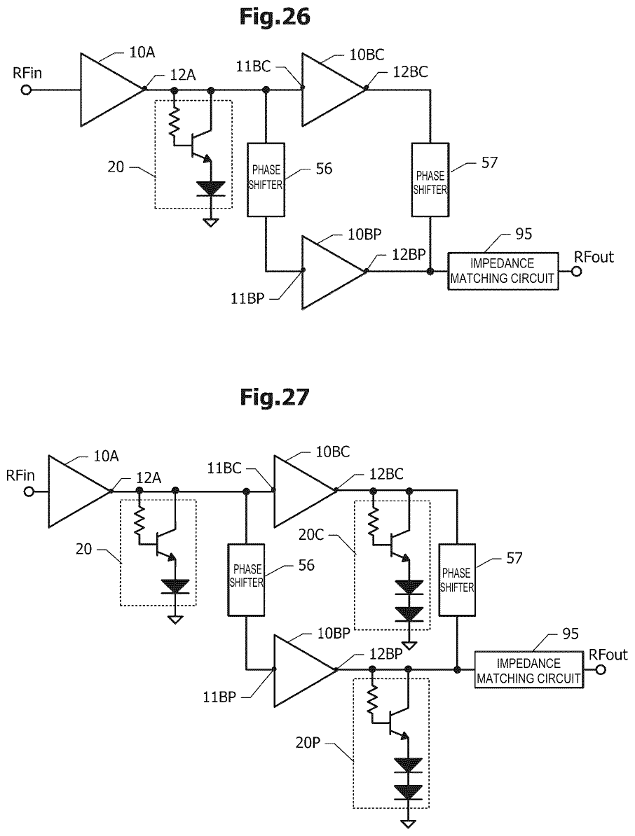

Next, variations of the ninth embodiment are described with reference to FIGS. 26 and 27. FIGS. 26 and 27 are equivalent circuit diagrams of amplifiers according to variations of the ninth embodiment.

As in the variation illustrated in FIG. 26, a clamping circuit 20 may be connected between the output node 12A of the initial-stage amplifier circuit 10A and the phase shifter 56. For example, the clamping circuit 20 has the same configuration as the clamping circuit 20 according to the sixth embodiment (FIG. 16A) or its variation. No clamping circuit is connected to either of the output nodes 12BC and 12BP of the output-stage amplifier circuits 10BC and 10BP. The clamping circuit 20 limits the power of radio frequency signals input to the output-stage amplifier circuits 10BC and 10BP. This in turn limits the output power of the output-stage amplifier circuits 10BC and 10BP.

As in the variation illustrated in FIG. 27, the clamping circuit 20 may be connected between the output node 12A of the initial-stage amplifier circuit 10A and the phase shifter 56, and the clamping circuits 20C and 20P may be connected to the output nodes 12BC and 12BP of the output-stage amplifier circuits 10BC and 10BP, respectively.

### Tenth Embodiment

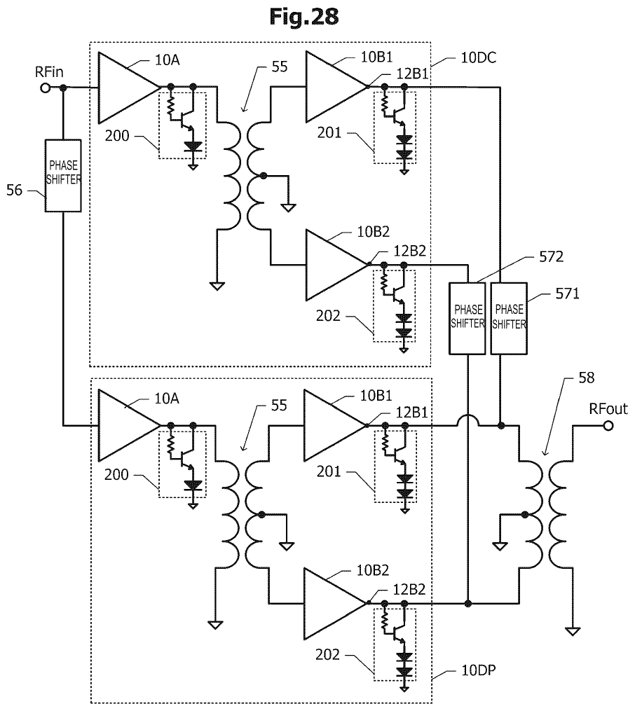

Next, an amplifier according to a tenth embodiment is described with reference to FIG. 28. Below, descriptions are omitted for components that are the same as those of the amplifier according to the ninth embodiment (FIG. 25).

FIG. 28 is an equivalent circuit diagram of an amplifier according to the tenth embodiment. In the ninth embodiment (FIG. 25), each of the amplifier circuits 10BC and 10BP, which respectively operate as a carrier amplifier and a peak amplifier of a Doherty amplifier circuit, is an amplifier circuit for a single-ended signal. In contrast, in the tenth embodiment, each of a carrier amplifier 10DC and a peak amplifier 10DP constituting a Doherty amplifier circuit includes a differential amplifier circuit. A phase shifter 56 is disposed on the input side of the carrier amplifier 10DC and the peak amplifier 10DP. A radio frequency signal RFin is input to the carrier amplifier 10DC and is also input to the peak amplifier 10DP via the phase shifter 56.

The carrier amplifier 10DC includes an initial-stage amplifier circuit 10A, a balanced-unbalanced conversion circuit 55, and output-stage amplifier circuits 10B1 and 10B2. The configurations of these components are the same as the configurations of the initial-stage amplifier circuit 10A, the balanced-unbalanced conversion circuit 55, and the output-stage amplifier circuits 10B1 and 10B2 of the amplifier according to the eighth embodiment (FIG. 22). However, the output-stage amplifier circuits 10B1 and 10B2 are biased to operate as carrier amplifiers.

A clamping circuit 200 is connected between the initial-stage amplifier circuit 10A and the balanced-unbalanced conversion circuit 55. Clamping circuits 201 and 202 are connected, respectively, to output nodes 12B1 and 12B2 of the output-stage amplifier circuits 10B1 and 10B2. The configuration of the clamping circuit 200 is the same as that of the clamping circuit 200 of the amplifier according to the variation of the eighth embodiment (FIG. 23). The configurations of the clamping circuits 201 and 202 are the same as those of the clamping circuits 201 and 202 of the amplifier according to the eighth embodiment (FIG. 22).

The basic configuration of the peak amplifier 10DP is the same as that of the carrier amplifier 10DC. However, the output-stage amplifier circuits 10B1 and 10B2 of the peak amplifier 10DP are biased to operate as peak amplifiers.

A radio frequency signal output from the amplifier circuit 10B1 of the carrier amplifier 10DC and phase-adjusted by a phase shifter 571 is combined with a radio frequency signal output from the amplifier circuit 10B1 of the peak amplifier 10DP, and the combined signal is input to one of the terminals of the primary coil of a balanced-unbalanced conversion circuit 58. Similarly, a radio frequency signal output from the amplifier circuit 10B2 of the carrier amplifier 10DC and phase-adjusted by a phase shifter 572 is combined with a radio frequency signal output from the amplifier circuit 10B2 of the peak amplifier 10DP, and the combined signal is input to the other one of the terminals of the primary coil of the balanced-unbalanced conversion circuit 58. Each of the phase shifters 571 and 572 may be implemented by, for example, a transformer.

The balanced-unbalanced conversion circuit 58 converts differential signals to a single-ended signal. The single-ended signal obtained by the conversion is output as a radio frequency signal RFout.

Next, advantageous effects of the tenth embodiment are described.

In the tenth embodiment, each of the carrier amplifier 10DC and the peak amplifier 10DP includes the clamping circuits 200, 201, and 202. Accordingly, similarly to the variation of the eighth embodiment (FIG. 24), the tenth embodiment makes it possible to finely adjust the output power limitation amounts for the output-stage amplifier circuits 10B1 and 10B2 of each of the carrier amplifier 10DC and the peak amplifier 10DP. This makes it possible to adjust the output power limitation amount such that the output power of each of the output-stage amplifier circuits 10B1 and 10B2 meets the required output without necessarily exceeding the breakdown limit.

Next, a variation of the tenth embodiment is described.

As in the ninth embodiment (FIG. 25), the clamping circuit 200 connected between the initial-stage amplifier circuit 10A and the balanced-unbalanced conversion circuit 55 may be omitted, and the clamping circuits 201 and 202 connected to the corresponding output nodes 12B1 and 12B2 of the output-stage amplifier circuits 10B1 and 10B2 may be retained. Also, as in the variation of the eighth embodiment (FIG. 26), the clamping circuits 201 and 202 connected to the corresponding output nodes 12B1 and 12B2 of the output-stage amplifier circuits 10B1 and 10B2 may be omitted, and the clamping circuit 200 connected between the initial-stage amplifier circuit 10A and the balanced-unbalanced conversion circuit 55 may be retained.

The embodiments described above are examples, and a partial exchange or a combination of components in different embodiments may be made. Descriptions of similar effects provided by different embodiments with similar configurations are not repeated. Furthermore, the present disclosure is not limited to the embodiments described above. For example, it would be obvious to a person skilled in the art that various modifications, improvements, and combinations of the embodiments can be made.

### REFERENCE SIGNS LIST

10, 10A, 10B, 10C radio frequency power amplifier circuit (amplifier circuit)
10B1, 10B2 amplifier circuits constituting differential amplifier circuit
10BC amplifier circuit operating as carrier amplifier
10BP amplifier circuit operating as peak amplifier
10DC carrier amplifier
10DP peak amplifier
11, 11A, 11B, 11BC, 11BP input node
12, 12A, 12B, 12B1, 12B2, 12BC, 12BP, 12C output node
20, 20A, 20B, 20C, 20P clamping circuit
20D multistage diode clamping circuit
21 resistor-connected transistor
22 transistor
22B base layer
22C collector layer
22E emitter layer
23 base-collector resistance element
24B base electrode
24C collector electrode
24E emitter electrode
25 diode
25A anode layer
25C cathode layer
26A anode electrode
26C cathode electrode
30 resistance variable circuit
31 switch element
32 resistance element
40B base wire
40C collector wire
40D wire
40E emitter wire
50 choke coil
55 balanced-unbalanced conversion circuit
56, 57 phase shifter
58 balanced-unbalanced conversion circuit
80 semiconductor substrate
81 epitaxial layer
81C conductive region
811 element isolation region
90 radio frequency signal source
92 impedance matching circuit
93 load
95 impedance matching circuit
200, 201, 202 clamping circuit
571, 572 phase shifter

1. A clamping circuit connected between a ground potential and a node through which a radio frequency signal passes, the clamping circuit comprising:
a plurality of clamping elements that are cascade connected with each other,
wherein each of the plurality of clamping elements is configured to be conductive when a voltage greater than or equal to a forward voltage is applied to the clamping element, and
wherein at least one of the plurality of clamping elements comprises a resistor-connected transistor, the resistor-connected transistor comprising a bipolar transistor and a base-collector resistance circuit element connected between a base and a collector of the bipolar transistor.

2. The clamping circuit according to claim 1, wherein each of the plurality of clamping elements comprises a resistor-connected transistor.

3. The clamping circuit according to claim 1, wherein one or more of the plurality of clamping elements comprises a plurality of diodes.

4. The clamping circuit according to claim 3, wherein at least one of the plurality of diodes comprises a diode-connected bipolar transistor.

5. The clamping circuit according to claim 1, further comprising:
a resistance variable circuit that is connected in parallel or in series with to the base-collector resistance circuit element and is configured to change a resistance value between the base and the collector of the resistor-connected transistor.

6. The clamping circuit according to claim 5, wherein the resistance variable circuit is connected in parallel with the base-collector resistance circuit element and comprises a switch connected in series with a resistance circuit element.

7. The clamping circuit according to claim 5, wherein the at least one of the plurality of clamping elements is connected to the resistance variable circuit at an intermediate point of the plurality of clamping elements, or at an end of the plurality clamping elements that is closer to the ground potential.

8. The clamping circuit according to claim 1,
wherein at least two of the plurality of clamping elements each comprise a resistor-connected transistor; and
the base-collector resistance circuit elements of each of the at least two clamping elements have different resistance values.

9. The clamping circuit according of claim 1,
wherein the clamping circuit is configured to be conductive when a peak value of a radio frequency voltage generated between the node and the ground potential exceeds a predetermined voltage value, and
wherein the clamping circuit is configured to limit an increase in the peak value of the radio frequency voltage between the node and the ground potential.

10. An amplifier comprising:
a first radio frequency power amplifier circuit that is configured to amplify a radio frequency signal input from an input node and to output an amplified radio frequency signal from an output node; and
the clamping circuit according to claim 1 that is connected between the input node or the output node of the first radio frequency power amplifier circuit, and the ground potential.

11. The amplifier according to claim 10, further comprising:
a second radio frequency power amplifier circuit,
wherein a radio frequency signal amplified by the second radio frequency power amplifier circuit is input to the input node of the first radio frequency power amplifier circuit.

12. An amplifier comprising:
a first radio frequency power amplifier circuit and a second radio frequency power amplifier circuit, each of which is configured to amplify a radio frequency signal input from an input node and to output an amplified radio frequency signal from an output node;
first and second clamping circuits according to claim 1, the first clamping circuit being connected between the output node of the first radio frequency power amplifier circuit and the ground potential, and the second clamping circuit being connected between the output node of the second radio frequency power amplifier circuit and the ground potential; and
a balanced-unbalanced conversion circuit that is configured to convert a single-ended signal to differential signals,
wherein the differential signals are input, respectively, to the input node of the first radio frequency power amplifier circuit and the input node of the second radio frequency power amplifier circuit.

13. An amplifier comprising:
a first radio frequency power amplifier circuit, a second radio frequency power amplifier circuit, and a third radio frequency power amplifier circuit, each of which is configured to amplify a radio frequency signal input from an input node and to output an amplified radio frequency signal from an output node;
the clamping circuit according to claim 1 that is connected between the output node of the third radio frequency power amplifier circuit and the ground potential; and
a balanced-unbalanced conversion circuit that is configured to convert a single-ended signal output from the output node of the third radio frequency power amplifier circuit into differential signals,
wherein the differential signals are input, respectively, to the input node of the first radio frequency power amplifier circuit and the input node of the second radio frequency power amplifier circuit.

14. An amplifier comprising:
a first radio frequency power amplifier circuit and a second radio frequency power amplifier circuit, each of which is configured to amplify a radio frequency signal input from an input node and to output an amplified radio frequency signal from an output node; and
first and second clamping circuits according to claim 1, the first clamping circuit being connected between the output node of the first radio frequency power amplifier circuit and a ground potential, and the second clamping circuit being connected between the output node of the second radio frequency power amplifier circuit and the ground potential,
wherein the first radio frequency power amplifier circuit is a carrier amplifier of a Doherty amplifier circuit and the second radio frequency power amplifier circuit is a peak amplifier of the Doherty amplifier circuit.

15. An amplifier comprising:
a first radio frequency power amplifier circuit, a second radio frequency power amplifier circuit, and a third radio frequency power amplifier circuit each of which is configured to amplify a radio frequency signal input from an input node and to output an amplified radio frequency signal from an output node;
the clamping circuit according to claim 1 that is connected between the output node of the third radio frequency power amplifier circuit and the ground potential; and
a phase shifter,
wherein the first radio frequency power amplifier circuit is a carrier amplifier of a Doherty amplifier circuit, and the second radio frequency power amplifier circuit is a peak amplifier of the Doherty amplifier circuit; and
wherein the radio frequency signal output from the output node of the third radio frequency power amplifier circuit is input to one of the input nodes of the first or second radio frequency power amplifier circuit, and is input to the other one of the input nodes of the first or second radio frequency power amplifier circuit via the phase shifter.
